(19) United States
(12) Patent Application Publication
(10) Pub. No.: US 2019/0086468 A1
(43) Pub. Date: Mar. 21, 2019

(54) DEVICE UNDER TEST TEMPERATURE SYNCHRONIZED WITH TEST PATTERN

(71) Applicant: Advantest Corporation, Tokyo (JP)

(72) Inventors: TAKATOSHI YOSHINO, San Jose, CA (US); DAVID ARMSTRONG, San Jose, CA (US); JINLEI LIU, San Jose, CA (US); TSE-KUN CHEN, San Jose, CA (US)

(21) Appl. No.: 16/138,029

(22) Filed: Sep. 21, 2018

Related U.S. Application Data
(60) Provisional application No. 62/561,604, filed on Sep. 21, 2017.

(51) Int. Cl. G01R 31/28; G01R 1/44

(52) U.S. Cl. CPC G01R 31/2874; G01R 1/44; G01R 31/2834

(57) ABSTRACT

Automated test equipment can generate feed-forward temperature profile information for a device under test (DUT), where the temperature data is determined from measurements performed during execution of a test pattern on the DUT, and can synchronize the temperature data and the cycles of the test pattern.

### REFERENCE TO RELATED APPLICATION

This application claims priority to U.S. Provisional Application No. 62/561,604, titled “Temperature Analysis Synchronized with Test Pattern on Automatic Test Equipment,” filed on Sep. 21, 2017, incorporated by reference in its entirety.

### BACKGROUND

In an automated, or automatic, test equipment (ATE) environment, the DUT (device under test, or the silicon, and also called a die) can experience temperature surges (spikes) during execution of the test pattern. Some test patterns can cause a rapid temperature surge that exceeds the capability to cool the DUT, which may result in unexpected and detrimental device behavior such as thermal runaway.

The junction temperature of a DUT is an important parameter for understanding the device's operating condition and power consumption. There are several conventional methods for measuring junction temperature, but each of these methods has limitations or problems. Some conventional methods use a discrete thermal sensor on the DUT interface board to measure the junction temperature inside the DUT. A problem with this method is that the sampling rate is often not fast enough nor is it well synchronized to the test execution to obtain a useful temperature profile during execution of the test sequence. Other conventional methods use a temperature measurement resource of the ATE and temperature sensors that are external to the DUT package, but such resources are problematic because of the remote location and high thermal resistance imposed by the package. Similarly, other conventional methods use an external temperature monitor, but such monitors only measure temperature on the surface of the DUT and do not measure junction temperature inside the DUT.

Also, it is critical to know which part of the executing test pattern caused a temperature surge so that designers or manufacturing process engineers can determine, for example, whether the surge is due to a design flaw or to a manufacturing issue. Information about which part of the test pattern caused a temperature surge can also be critical to identifying and understanding the root cause of the temperature surges or thermal runaway. Another problem with conventional testing methods is that it is difficult to diagnose which part of the test pattern caused a surge in temperature or thermal runaway.

### SUMMARY

Embodiments according to the present invention address the above limitations, and specifically address the issue of temperature measurements synchronized (correlated) to the test execution, which allows for more accurate test results as well as faster test execution.

In embodiments according to the present invention, automated test equipment (ATE) determines accurate temperature data (junction temperatures) for the device under test (DUT) from temperature measurements performed during execution of the test pattern on the DUT, and synchronizes the temperature data and the cycles of the test pattern. The synchronized temperature data and test cycles may be referred to herein as a synchronized temperature profile. In an embodiment, power consumption measurements of the DUT during execution of the test pattern on the DUT and the cycles of the test pattern are also synchronized.

Consequently, personnel such as design, manufacturing, and test engineers can quickly and effectively gain an understanding of how the DUT operated during the testing, determine which part of the test pattern caused a temperature surge or spike should one occur, and implement solutions to maintain stable or acceptable thermal conditions during subsequent testing and when the device is later mass-produced and operated.

In embodiments, the ATE receives voltage levels from a thermal sensor (e.g., a thermal diode) in the DUT during execution of the test pattern on the DUT, and determines junction temperatures of the DUT during execution of the test pattern by measuring these voltage levels. In embodiments, the ATE includes a differential sampler that measures the voltage levels received from the thermal sensor in the DUT. Because the voltage levels are measured by an ATE measurement resource (e.g., the differential sampler), and because the ATE is also driving execution of the test pattern on the DUT, the ATE can be used to perform the synchronized measurements (of the junction temperatures) and the cycles through the test plan to generate a synchronized temperature profile.

In embodiments, the ATE controls cooling of the DUT during subsequent execution(s) of the test pattern on the DUT using the synchronized temperature profile as reference data. In an embodiment, the ATE feeds the synchronized temperature profile to a handler operable for cooling the DUT. This is referred to herein as feed-forward control. The synchronized temperature profile can be used to identify beforehand which cycles of the test pattern may cause a temperature surge or spike, and thus it allows the handler to start cooling the DUT before those cycles are executed, to suppress temperature surges and prevent thermal runaway when those cycles are executed. Feed-forward control based on the synchronized temperature profile thus provides more agile and precise thermal control during testing.

In embodiments, during testing, the cooling system accepts both the feed-forward temperature profile information and real-time temperature measurement data, in order to respond to both the anticipated thermal profile as described above and real-time device-specific thermal data. The feed-forward temperature profile aligns the cooling system to the expected device temperature. Because the cooling system is pre-aligned to the expected device temperature based on the feed-forward temperature profile, the real-time adjustments become fine-tuning steps that are inherently faster and more accurate. The power consumption measurements synchronized with cycles of the test pattern can be used to further enhance thermal control during testing.

In summary, embodiments according to the present invention include a system that can measure an accurate junction temperature profile for a given test sequence. The resulting synchronized temperature profile can be used as reference data for precise thermal control of the DUT, and can also be used to diagnose a root cause of each temperature surge or spike that might occur. In combination with adjustments based on real-time temperature measurements, the precision of the thermal control is further enhanced.

These and other objects and advantages of the various embodiments of the present invention will be recognized by those of ordinary skill in the art after reading the following detailed description of the embodiments that are illustrated in the various drawing figures.

### BRIEF DESCRIPTION OF THE DRAWINGS

The present invention is illustrated by way of example, and not by way of limitation, in the figures of the accompanying drawings and in which like reference numerals refer to similar elements.

FIG. 1 is a block diagram illustrating automated test equipment (ATE) and a device under test (DUT) in embodiments according to the present invention.

FIG. 2 is a block diagram illustrating an ATE and DUT in embodiments according to the present invention.

FIG. 3 is a block diagram illustrating an ATE and DUT in embodiments according to the present invention.

FIG. 4 is a block diagram illustrating an ATE and DUT in embodiments according to the present invention.

FIG. 5 is a flowchart illustrating a testing process in embodiments according to the present invention.

FIG. 6 is a block diagram illustrating an ATE and DUT in embodiments according to the present invention.

FIG. 7 is a block diagram illustrating an ATE, DUT, and handler in embodiments according to the present invention.

FIGS. 8A and 8B are examples illustrating the effect of feed-forward control on junction temperature in embodiments according to the present invention.

FIG. 9 is a flowchart of an example of a method implemented by a system including an ATE for testing a DUT in embodiments according to the present invention.

### DETAILED DESCRIPTION

Reference will now be made in detail to embodiments of the present invention, examples of which are illustrated in the accompanying drawings. While the present invention will be discussed in conjunction with the following embodiments, it will be understood that they are not intended to limit the present invention to these embodiments alone. On the contrary, the present invention is intended to cover alternatives, modifications, and equivalents which may be included with the spirit and scope of the present invention as defined by the appended claims. Furthermore, in the following detailed description of the embodiments of the present invention, numerous specific details are set forth in order to provide a thorough understanding of the present invention. However, embodiments of the present invention may be practiced without these specific details. In other instances, well-known methods, procedures, components, and circuits have not been described in detail so as not to unnecessarily obscure aspects of the present invention.

Some portions of the detailed descriptions that follow are presented in terms of procedures, logic blocks, processing, and other symbolic representations of operations on data bits within a computer memory. These descriptions and representations are the means used by those skilled in the data processing arts to most effectively convey the substance of their work to others skilled in the art. In the present application, a procedure, logic block, process, or the like, is conceived to be a self-consistent sequence of steps or instructions leading to a desired result. The steps are those utilizing physical manipulations of physical quantities. Usually, although not necessarily, these quantities take the form of electrical or magnetic signals capable of being stored, transferred, combined, compared, and otherwise manipulated in a computer system. It has proven convenient at times, principally for reasons of common usage, to refer to these signals as transactions, bits, values, elements, symbols, characters, samples, pixels, or the like.

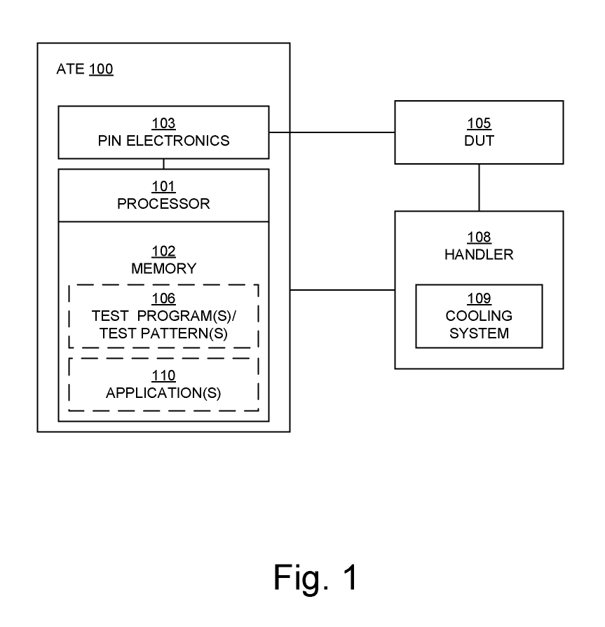

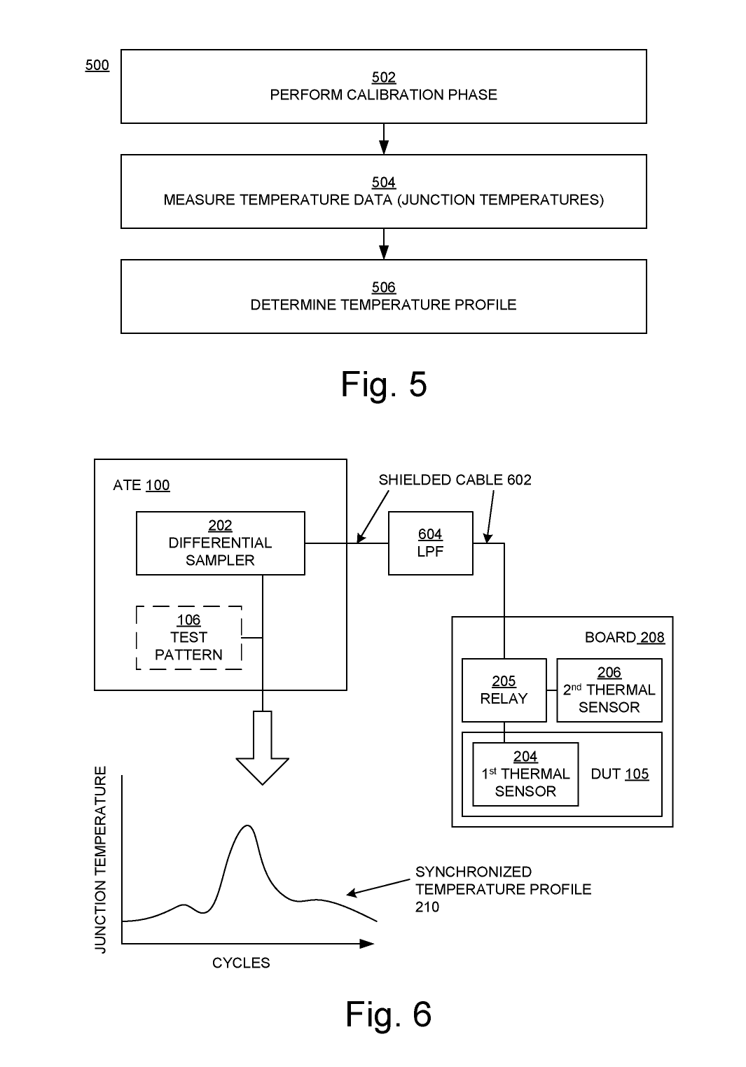

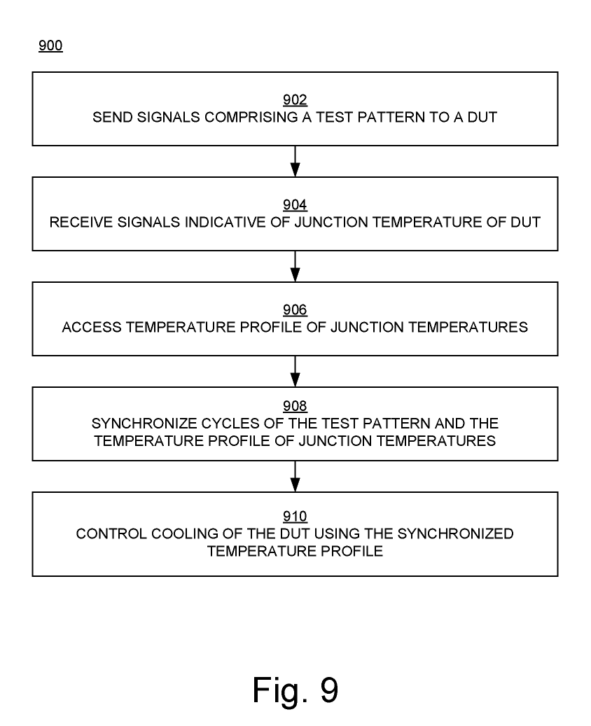

It should be borne in mind, however, that all of these and similar terms are to be associated with the appropriate physical quantities and are merely convenient labels applied to these quantities. Unless specifically stated otherwise as apparent from the following discussions, it is appreciated that throughout the present disclosure, discussions utilizing terms such as “accessing,” “measuring,” “synchronizing,” “calibrating,” “applying,” “receiving,” “sending,” “determining,” “controlling,” “feeding,” “executing,” or the like, refer to actions and processes (e.g., the flowcharts 500 and 900 of FIGS. 5 and 9, respectively) of a computer system or similar electronic computing device or processor (e.g., the automated test equipment 100 of FIG. 1). The computer system or similar electronic computing device manipulates and transforms data represented as physical (electronic) quantities within the computer system memories, registers or other such information storage, transmission or display devices.

Embodiments described herein may be discussed in the general context of computer-executable instructions residing on some form of computer-readable storage medium, such as program modules, executed by one or more computers or other devices. By way of example, and not limitation, computer-readable storage media may comprise non-transitory computer-readable storage media and communication media; non-transitory computer-readable media include all computer-readable media except for a transitory, propagating signal. Generally, program modules include routines, programs, objects, components, data structures, etc., that perform particular tasks or implement particular abstract data types. The functionality of the program modules may be combined or distributed as desired in various embodiments.

Computer storage media includes volatile and nonvolatile, removable and non-removable media implemented in any method or technology for storage of information such as computer-readable instructions, data structures, program modules or other data. Computer storage media includes, but is not limited to, random access memory (RAM), read only memory (ROM), electrically erasable programmable ROM (EEPROM), flash memory or other memory technology, compact disk ROM (CD-ROM), digital versatile disks (DVDs) or other optical storage, magnetic cassettes, magnetic tape, magnetic disk storage or other magnetic storage devices, or any other medium that can be used to store the desired information and that can accessed to retrieve that information.

Communication media can embody computer-executable instructions, data structures, and program modules, and includes any information delivery media. By way of example, and not limitation, communication media includes wired media such as a wired network or direct-wired connection, and wireless media such as acoustic, radio frequency (RF), infrared, and other wireless media. Combinations of any of the above can also be included within the scope of computer-readable media.

FIG. 1 is a block diagram illustrating a system that includes automated test equipment (ATE) 100 for testing a device under test (DUT) 105 in embodiments according to the present invention. In the example of FIG. 1, the ATE 100 includes a processor (e.g., a test processor) 101 and memory 102. The pin-electronics 103 deliver the test sequence to the DUT and sense the response of the DUT to this test stimulus. The ATE 100 can include components in addition to those illustrated or described herein.

The ATE 100 can interface with a handler 108 that provides a test platform or device interface board for the DUT 105. In embodiments, the handler 108 includes a cooling system 109 (e.g., an active thermal control, ATC, system) that can be used to cool the DUT 105 during testing.

The processor 101 is configured to provide signals to the DUT 105 on the basis of a sequence of instructions that define and implement a test program 106 that can, for example, be stored or buffered in the memory 102. The instructions define test vectors that make up a test pattern. The processor 101 is configured to map a test vector into a set (waveform) of signal states or signal transitions (cycles) that are executed on or by the DUT 105 during testing. A cycle may correspond to a single test vector.

As will be described below, the processor 101 can also execute one or more applications 110 that can synchronize the junction temperature of the DUT 105 and cycles of the test pattern, and/or that can synchronize power consumption of the DUT and cycles of the test pattern, and/or that can be used to control cooling of the DUT using the cooling system 109 of the handler 108.

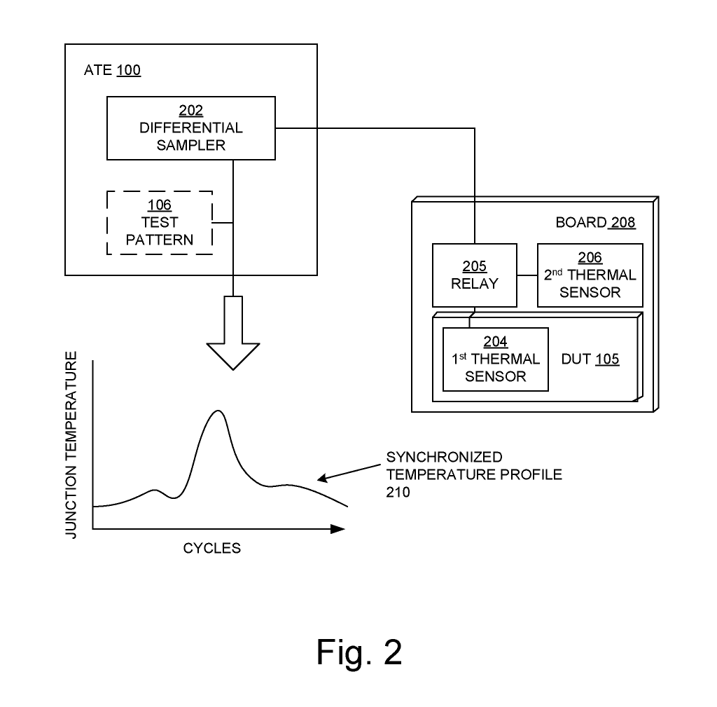

FIG. 2 is a block diagram illustrating the ATE 100, the DUT 105, and a device interface board (load board) 208 in embodiments according to the present invention. In the FIG. 2 embodiments, the ATE 100 includes a differential sampler 202, the DUT 105 is mounted on the load board 208 and includes a first thermal sensor 204, and the load board includes a relay 205 and a second thermal sensor 206. The first thermal sensor 204 is internal to the DUT 105 and can be any type of device that can be used to determine a temperature, and the second thermal sensor 206 is external to the DUT and can also be any type of device that can be used to determine a temperature. The first and second thermal sensors 204 and 206 can each be the same type of device or they can be different types of devices, such as, but are not limited to, a thermal diode, resistor (thermistor), or capacitor, a thermocouple, or a microelectromechanical (MEM) device.

The relay 205 is used to connect the first thermal sensor 204 to the second thermal sensor 206 or to the ATE 100, specifically to the differential sampler 202. In an embodiment, the relay 205 is used to connect the second thermal sensor 206 to the differential sampler 202 during a calibration phase, and to connect the first thermal sensor 204 to the differential sampler during testing.

In an embodiment, during testing of the DUT 105 (during execution of the test pattern 106), the ATE 100 uses a signal (e.g., voltage level) received from the first thermal sensor 204 and measured by the differential sampler 202 to determine temperature data of the DUT, specifically a temperature profile comprising junction temperatures of the DUT versus time. (A voltage level received from the first thermal sensor 204 is the voltage across that thermal sensor.) In an embodiment, the temperature data (profile) is stored in memory (e.g., the memory 102 of FIG. 1). In embodiments, the ATE 100 then correlates or synchronizes the temperature profile and the cycles of the test sequence.

Differential sampling is advantageous for noise immunity, particularly when the first thermal sensor 204 is not ground-referenced. The differential sampler 202 has a high-speed sampling mode (e.g., a sampling rate of ten mega-samples per second). Thus, the differential sampler 202 can determine temperatures quickly. This in turn allows better alignment (synchronization) between the temperature profile and the cycles of the test pattern 106.

In embodiments according to the present invention, the ATE 100 synchronizes the temperature profile and the cycles of the test pattern 106 to produce a profile 210 of junction temperature versus cycle. The profile 210 may be referred to herein as a synchronized temperature profile. In an embodiment, power consumption measurements of the DUT 105 during execution of the test pattern 106 on the DUT and the cycles of the test pattern are also synchronized.

The ATE 100 can synchronize the temperature profile and cycles of the test pattern 106 in real time as the testing is being performed. Alternatively, the temperature profile can be stored in the memory 102, as mentioned above, and so can be synchronized with the cycles of the test pattern 106, also stored in memory, at a later time. In general, the ATE 100 can access the temperature data (temperature profile) that is determined from measurements performed during execution of the test pattern 106 on the DUT 105, and can synchronize the temperature profile and the cycles of the test pattern.

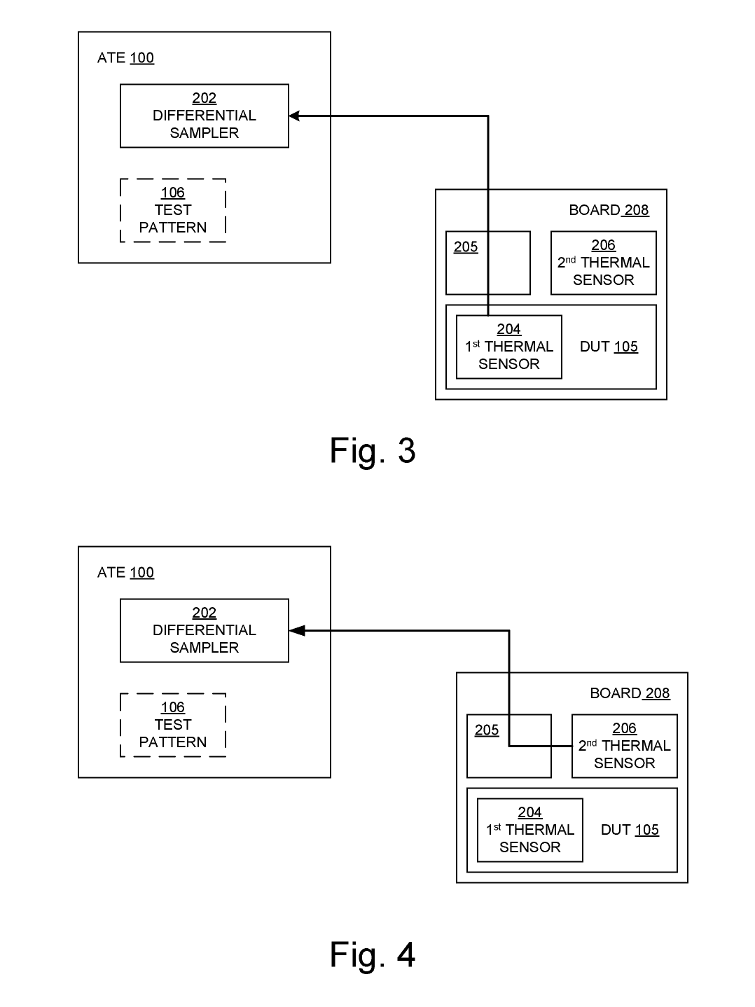

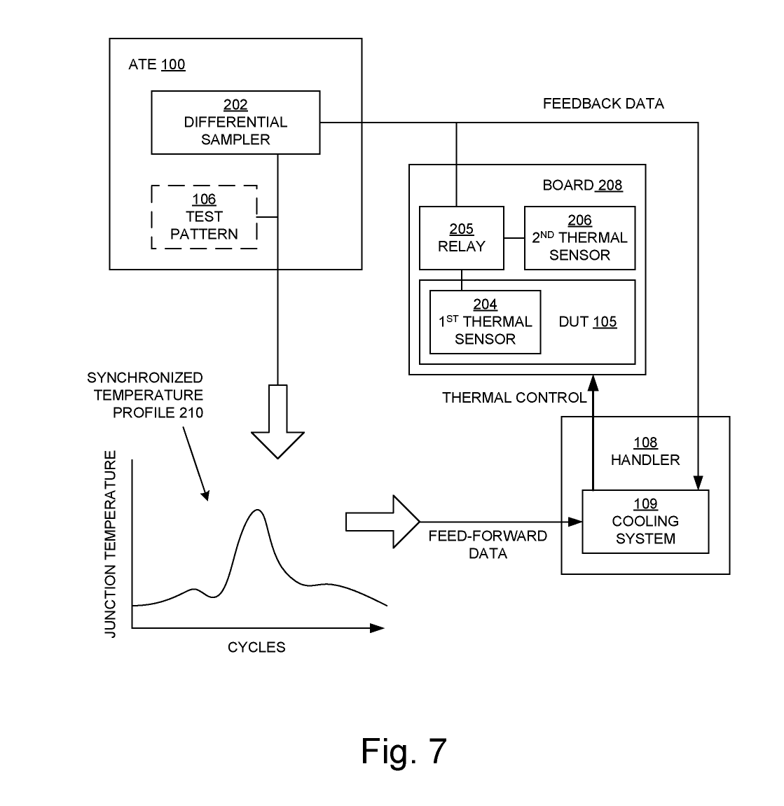

With reference to FIG. 3, in an embodiment, the on-die first thermal sensor 204 measures a voltage level. The second thermal sensor 206, which may be inherently slower and less accurate than the first thermal sensor 204, is used for real-time temperature feedback to the cooling system 109, as described further in conjunction with FIG. 7. The second thermal sensor 206 can also be used for real-time temperature control should the first thermal sensor 204 become unavailable during the test execution. In the latter situation, the relay 205 changes state to allow the real-time thermal feedback to continue uninterrupted to the cooling system 109.

With reference to FIG. 4, the first thermal sensor 204 on the DUT 105 may need to be accessed directly by the test program. During that time, the second thermal sensor 206 provides a feedback signal to the ATC system 109.

FIG. 5 is a flowchart 500 illustrating a testing process in embodiments according to the present invention. In an embodiment, the flowchart 300 is implemented using the ATE 100 of FIG. 1, operating in conjunction with the DUT 105 and the handler 108.

In an embodiment, in block 502 of FIG. 5, with reference also to FIG. 2, a calibration phase is performed, to calibrate the voltage levels measured by the second thermal sensor 206 and the voltage levels measured by the ATE 100 (e.g., by the differential sampler 202) that provide the thermal response of the DUT to the test sequence.

In an embodiment, in the calibration phase, junction temperature is measured by the second thermal sensor 206. The second thermal sensor 206 is optimized for thermal measurement and receives or measures the voltage level of the first thermal sensor 204. At the same time, the voltage level of the first thermal sensor 204 is measured by the digital sampler 202. The two voltage level values are used to determine a calibration factor that can be subsequently used for the measurement of junction temperature with the first thermal sensor 204. To minimize any noise-induced errors, the temperature of the DUT 105 is stabilized before taking these two measurements, with the inclusion of a low-pass-filter 604 as shown in FIG. 6.

In block 504 of FIG. 5, with reference also to FIGS. 1 and 2, junction temperatures of the DUT 105 are measured. During execution of the test pattern 106 on the DUT 105, the voltage level of the first thermal sensor 204 is measured by the differential sampler 202 over time, and these voltage levels are used to determine junction temperatures.

In block 506 of FIG. 5, the junction temperatures are used to determine a temperature profile for the DUT 105 during the testing.

Because the voltage levels are measured by a measurement resource of the ATE 100 (e.g., by the differential sampler 202), and because the ATE is also driving execution of the test pattern 106 on the DUT 105, the ATE can be used to provide synchronize the temperature profile and cycles of the test plan to generate the synchronized test profile.

FIG. 6 is a block diagram illustrating the ATE 100 and DUT 105 in embodiments according to the present invention. In the FIG. 6 embodiments, a shielded cable 602 (e.g., a shielded twist cable) is used to couple the ATE 100 (specifically, the differential sampler 202) to the DUT 105, and a low-pass filter (LPF) 604 is coupled to the cable. These features reduce noise and improve the quality of the collected temperature data.

FIG. 7 is a block diagram illustrating the ATE 100, DUT 105, and handler 108 in embodiments according to the present invention. In the FIG. 7 embodiments, during execution of a test pattern on the DUT 105, the junction temperatures determined by the second thermal sensor 206 are fed to the cooling (e.g., ATC) system 109. That is, the handler 108 receives direct junction temperature readings in real time as feedback data that can be used to adjust the degree of cooling provided by the cooling system 109 while a test pattern is being executed. For example, if the feedback data indicates that the junction temperature is increasing during testing, then the cooling system 109 can increase the degree of cooling.

As described above (FIG. 2), the voltage levels supplied by the first thermal sensor 204 are supplied to the differential sampler 202, the ATE 100 uses these voltage levels to determine junction temperatures, and the ATE synchronizes the junction temperature data and the cycles of the test pattern 106 to produce a synchronized temperature profile 210. The ATE 100 and the handler 108 thus share the same source (e.g., the first thermal sensor 204) for junction temperature measurements.

In embodiments according to the present invention, the synchronized temperature profile 210 is fed to the handler 108 (e.g., to the cooling system 109). That is, the handler 108 receives the synchronized temperature profile 210 as feed-forward data that can be used to adjust the degree of cooling provided by the cooling system 109 while a test pattern is being executed. More specifically, the synchronized temperature profile 210 can be used as reference data to identify which cycles of the test pattern may cause a temperature surge or spike. This allows the handler 108 and cooling system 109 to anticipate a temperature surge and to start to increase cooling of the DUT 105 before those cycles are executed, to suppress temperature surges and prevent thermal runaway. Feed-forward control based on the synchronized temperature profile 210 thus provides more precise thermal control during testing.

For example, if a test pattern causes a rapid temperature surge exceeding the performance limit of the normal feedback thermal control, feed-forward control can achieve a stable thermal condition in the DUT 105 by starting cooling of the DUT before the temperature rise begins, suppressing the rapid thermal change. Because the synchronized temperature profile 210 identifies the cycle in the test pattern at which the temperature rise begins, it can be utilized as a reference for a predefined thermal control sequence. Also, because the thermal transitions in a particular test pattern tend to be similar for different instances of a specific semiconductor product model, the synchronized temperature profile 210 can be used for as a reference through the entire production lot.

In embodiments, the cooling system 109 accepts both the feed-forward temperature profile information and real-time temperature measurement data, in order to respond to both the anticipated thermal profile as described above and real-time device-specific thermal data. The feed-forward temperature profile aligns the cooling system 109 to the expected device (DUT) temperature. Because the cooling system 109 is pre-aligned to the expected device temperature based on the feed-forward temperature profile, the real-time adjustments become fine-tuning steps that are inherently faster and more accurate. The power consumption measurements synchronized with cycles of the test pattern can also be used to further enhance thermal control during testing.

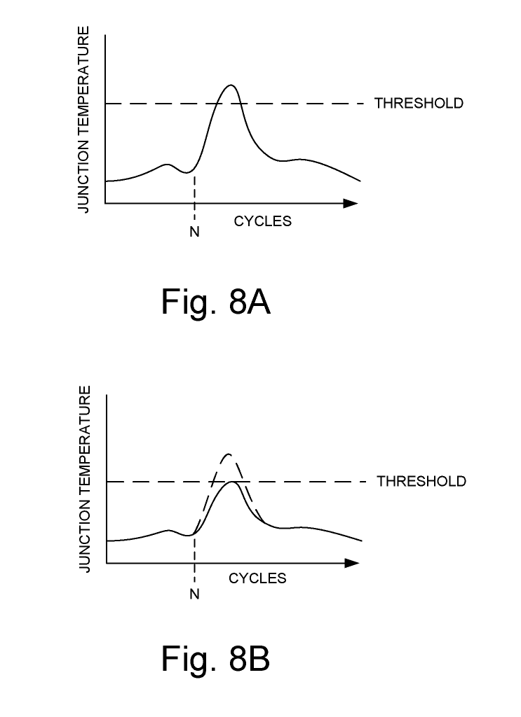

FIGS. 8A and 8B are examples illustrating the effect of feed-forward control on junction temperature in embodiments according to the present invention. In FIG. 8A, a test pattern is executed and only feedback control is used. For example, only feedback control may be used when a particular test pattern is first executed, to accumulate temperature data that can be used to identify which parts/cycles of the test pattern cause temperature surges, the magnitude of the temperature surge, and to generate a synchronized temperature profile for that test pattern.

In FIG. 8B, the same test pattern is executed and feed-forward control is also used. Thus, for example, at cycle N, where the temperature surge starts to increase to a level that may be unacceptable as indicated by the threshold in FIG. 8A, feed-forward control can be used to suppress the temperature surge as shown in FIG. 8B. Because the magnitude of the temperature surge is determined when only feedback control is used, the amount of cooling needed to suppress the temperature surge and maintain stable thermal control can also be determined in advance and applied at cycle N when the test pattern is subsequently executed.

FIG. 9 is a flowchart 900 of an example of a method for testing a DUT in embodiments according to the present invention. In an embodiment, the flowchart 1000 is implemented using the ATE 100 of FIG. 1.

In block 902 of FIG. 9, during execution of a test pattern on the DUT, the ATE sends signals comprising the test pattern to the DUT.

In block 904, the ATE receives signals indicative of junction temperatures of the DUT during execution of the test pattern on the DUT. In an embodiment, the signals are received by a differential sampler of the ATE, from a thermal sensor in the DUT, and the signals indicate voltage levels across the thermal sensor. The voltage levels are used to determine a temperature profile of the DUT during testing. In an embodiment, the temperature profile is stored in memory.

In block 906, the ATE accesses the temperature profile (junction temperatures) for the DUT.

In block 908, the ATE synchronizes cycles of the test pattern and the temperature profile (junction temperatures) to generate a synchronized temperature profile. The ATE, knowing the anticipated thermal response from the synchronized temperature profile, can more effectively manage the handler's DUT cooling system. In an embodiment, the ATE also synchronizes power consumption measurements of the DUT during execution of the test pattern on the DUT and the cycles of the test pattern to further enhance anticipation of the device's cooling requirements. In another embodiment, real-time DUT temperature data is also provided to the cooling system.

In block 910, in embodiments, the cooling of the DUT during subsequent execution of the test pattern on the DUT is determined by the previously determined synchronized temperature profile, the real-time DUT temperature data, and the power measurement results available to the test program and the ATE. In an embodiment, the ATE simply feeds the synchronized temperature profile to a handler that is operable for cooling the DUT. In another embodiment, the ATE feeds a thermal control signal that it has calculated based on the three inputs mentioned above (the previously determined synchronized temperature profile, real-time temperature data, and power measurement results). The handler's cooling system (e.g., ATC system) will use the control signals to respond to both expected temperature surges and unexpected temperature changes, as previously described herein.

In summary, embodiments according to the present invention include a system that can generate accurate junction temperature data for a DUT and synchronize the temperature data with cycles of a test pattern that was executed on the DUT.

The resulting synchronized temperature profile can be used to diagnose a root cause of each temperature surge or spike that might occur. More specifically, the synchronized temperature profile can be used to determine which part of the executing test pattern caused a temperature surge so that personnel such as designers or manufacturing process engineers can determine, for example, whether the surge is due to a design flaw or to a manufacturing issue. The synchronized temperature profile can also be used to identify and understand the root cause of temperature surges or thermal runaway. Consequently, personnel can quickly and effectively gain an understanding of how the DUT operated during the testing, determine which part (cycle) of the test pattern caused a temperature surge or spike should one occur, and implement solutions to maintain stable or acceptable thermal conditions during subsequent testing and when the device is later mass-produced and operated.

The synchronized temperature profile can also be used as reference data for precise thermal control (feed-forward control) of the DUT. Feed-forward control based on the synchronized temperature profile provides more precise thermal control during testing. Combined with synchronized power consumption measurements and/or real-time temperature data, feed-forward control based on the synchronized temperature profile provides even more precise thermal control during testing.

Thus, embodiments according to the present invention solve the problems with conventional testing that are described previously herein.

While the foregoing disclosure sets forth various embodiments using specific block diagrams, flowcharts, and examples, each block diagram component, flowchart step, operation, and/or component described and/or illustrated herein may be implemented, individually and/or collectively, using a wide range of hardware, software, or firmware (or any combination thereof) configurations. In addition, any disclosure of components contained within other components should be considered as examples because many other architectures can be implemented to achieve the same functionality.

The process parameters and sequence of steps described and/or illustrated herein are given by way of example only and can be varied as desired. For example, while the steps illustrated and/or described herein may be shown or discussed in a particular order, these steps do not necessarily need to be performed in the order illustrated or discussed. The various example methods described and/or illustrated herein may also omit one or more of the steps described or illustrated herein or include additional steps in addition to those disclosed.

In the foregoing specification, embodiments of the invention have been described with reference to numerous specific details that may vary from implementation to implementation. Thus, the sole and exclusive indicator of what is, and is intended by the applicant to be, the invention is the set of claims that issues from this application, in the specific form in which such claims issue, including any subsequent correction. Hence, no limitation, element, property, feature, advantage, or attribute that is not expressly recited in a claim should limit the scope of such claim in any way. Accordingly, the specification and drawings are to be regarded in an illustrative rather than a restrictive sense.

What is claimed is:

1. A method performed by a system comprising automated test equipment (ATE), the method comprising:
accessing temperature data for a device under test (DUT), the temperature data determined from measurements performed during execution of a test pattern on the DUT; and
synchronizing the temperature data and cycles of the test pattern.

2. The method of claim 1, further comprising controlling cooling of the DUT during subsequent execution of the test pattern on the DUT using the temperature data synchronized with the cycles of the test pattern.

3. The method of claim 2, further comprising feeding the temperature data synchronized with the cycles of the test pattern to a handler operable for cooling the DUT.

4. The method of claim 2, further comprising synchronizing power consumption measurements of the DUT during execution of the test pattern on the DUT and the cycles of the test pattern.

5. The method of claim 4, further comprising controlling cooling of the DUT during the execution of the test pattern on the DUT using the power consumption measurements synchronized with the cycles of the test pattern.

6. The method of claim 5, further comprising controlling cooling of the DUT using real-time temperature data measured during the execution of the test pattern on the DUT.

7. A system comprising:
automated test equipment (ATE), comprising:
a processor; and
memory coupled to the processor, wherein the processor is configured to execute instructions stored in the memory, the instructions when executed causing the system to perform a method comprising:
accessing temperature data for a device under test (DUT), the temperature data determined from measurements performed during execution of a test pattern on the DUT; and
synchronizing the temperature data and cycles of the test pattern.

8. The system of claim 7, wherein the ATE further comprises a differential sampler operable to measure a voltage level received from the DUT, wherein the voltage level is indicative of a junction temperature of the DUT.

9. The system of claim 7, wherein the method further comprises controlling cooling of the DUT during subsequent execution of the test pattern on the DUT using the temperature data synchronized with the cycles of the test pattern.

10. The system of claim 9, wherein the ATE is configured for coupling with a handler operable for cooling the DUT, wherein the method further comprises feeding the temperature data synchronized with the cycles of the test pattern to the handler.

11. The system of claim 9, wherein the method further comprises synchronizing power consumption measurements of the DUT during execution of the test pattern on the DUT and the cycles of the test pattern.

12. The system of claim 11, wherein the method further comprises controlling cooling of the DUT during the execution of the test pattern on the DUT using the power consumption measurements synchronized with the cycles of the test pattern.

13. The system of claim 12, wherein the method further comprises controlling cooling of the DUT using real-time temperature data measured during the execution of the test pattern on the DUT.

14. The system of claim 7, further comprising a shielded cable coupled to the ATE and configured for connecting with the DUT.

15. The system of claim 14, further comprising a low pass filter coupled to the shielded cable.

16. A method of testing a device under test (DUT), the method comprising:
during execution of a test pattern on the DUT, sending signals comprising the test pattern to the DUT;
receiving signals indicative of junction temperatures of the DUT during the execution of the test pattern on the DUT; and
synchronizing cycles of the test pattern and the junction temperatures.

17. The method of claim 16, further comprising controlling cooling of the DUT during subsequent execution of the test pattern on the DUT using the temperature data synchronized with the cycles of the test pattern, wherein said controlling comprises feeding the temperature data synchronized with the cycles of the test pattern to a handler operable for cooling the DUT.

18. The method of claim 16, further comprising synchronizing power consumption measurements of the DUT during execution of the test pattern on the DUT and the cycles of the test pattern.

19. The method of claim 18, wherein said controlling further comprises feeding the power consumption measurements synchronized with the cycles of the test pattern to the handler.

20. The method of claim 19, wherein said controlling further comprises feeding real-time temperature data measured during the execution of the test pattern on the DUT to the handler.
